(19) United States
(12) Patent Application Publication
(10) Pub. No.: US 2012/0170342 A1
(43) Pub. Date: Jul. 5, 2012

(54) U-SOCKET, AN AC SOCKET WITH PORT POWERING DEVICE, SWITCH AND FAULT DETECT LAMP

(76) Inventor: Patrick Manning, Los Gatos, CA (US)

(21) Appl. No.: 12/870,721

(22) Filed: Aug. 27, 2010

Related U.S. Application Data
(60) Provisional application No. 61/305,707, filed on Feb. 18, 2010.

(51) Int. Cl. H02M 7/02; H05K 13/00

(52) U.S. Cl. 363/146; 29/401.1

(57) ABSTRACT

An AC fixture has one or more AC sockets, and a port powering or charging device with one or more ports. The port powering or charging device has a circuit board with a power circuit which is configured to convert AC power, from AC wires connected to the AC socket, to DC power. The power circuit is configured to deliver the DC power to the one or more ports, which may be a USB, FireWire, mini-USB, HDMI or other port or combination of ports. In a further example, a communication circuit provides signal and data connections over the AC wiring, to one or more of the ports. In a still further example, a lamp or other indicator visible on a faceplate of the device is activated upon a reversed connection of the AC wires, to alert an installer or a user of a wiring fault.

### CROSS-REFERENCE. TO RELATED APPLICATION

This application claims priority from provisional application Ser. No. 61/305,707, filed Feb. 18, 2010.

### TECHNICAL FIELD

This invention relates to the field of computing and peripheral devices interconnection and to the field of Alternating Current (AC) fixtures.

### BACKGROUND

A Universal Serial Bus (USB) device, such as a computer peripheral, may be charged or powered by DC electrical power from the USB port to which it is connected. Commonly, a USB device is connected to a personal computer using a USB cable, with the USB cable plugged into a USB port of the personal computer. The personal computer provides DC power from the USB port of the personal computer and through the USB cable to the USB device.

USB is a known standard for providing a data connection and/or power to a USB connectable device, via a USB port. The USB Implementers Forum (USB-IF) is the managing body of USB specifications. A USB port providing data and power to a device is a USB data and power port. A USB port providing power to a device is a USB power port. A USB port providing data to a device is a USB data port.

There are various sizes of USB connectors e.g. standard, mini and micro. There are two main types of USB connectors, type A for a downstream-port of a USB host or hub and type B for a peripheral. Each type of connector has a plug and a receptacle. A USB type A plug of a USB cable inserts into a USB type A receptacle on the USB host or hub. A USB type B plug of a USB cable inserts into an upstream receptacle of a peripheral. A standard type A USB connector has four pins, and type B has four pins. Other sizes of USB connectors may have more than four pins, as may proprietary versions of USB connectors.

Alternating Current (AC) sockets have many variations worldwide. In North America, the standard three prong AC socket conforms to the National Electrical Manufacturers Association NEMA 5-15 standard for a 15 Amp 125 Volt grounded socket. Many AC sockets are approved by the Underwriters Laboratory (UL).

### SUMMARY

It is a goal of the present embodiments to provide DC power from a USB port at an AC fixture, for use by a USB device connected by a USB cable to the USB port at the AC fixture.

It is a further goal of the present embodiments to provide a data connection from a USB port at an AC fixture, for use by a USB device connected by a USB cable to the USB port at the AC fixture, the data being communicated through the AC wirings connected with the AC fixture.

It is a still further goal of the present embodiments to provide a method for modifying an existing AC fixture such that the modified AC fixture provides a powered USB port.

These and other goals are satisfied by a port powering or charging device having a circuit board and a housing. The circuit board is connectable to an AC socket and has a power circuit and a port. The housing contains the circuit board. The AC socket is mountable to the housing. The housing is mountable to or within a wall of a dwelling. The power circuit is configured to convert AC power from the AC socket to DC power, and deliver the DC power to the port.

The port may be a USB port, a FireWire, a mini USB or an HDMI port. The port powering or charging device may include a fault circuit configured to activate an indicator, such as a lamp, in response to a wiring fault of the AC socket.

An example of the Port powering or charging device is a USB port powering or charging device. The USB port powering or charging device has an AC socket, a circuit board and a housing. The AC socket is connectable to AC wires, and is mounted in the housing. The circuit board is connected to the AC socket, and has a power circuit and a USB port. The housing contains the circuit board, and is mountable to or within a wall of a dwelling. The power circuit is configured to convert AC power from the AC socket to DC power, and deliver the DC power to the USB port.

The USB port powering or charging device may include a lamp mounted to the circuit board and a tester circuit attached to the lamp and to the AC socket. The tester circuit is configured to activate the lamp upon a wiring reversal at the AC socket.

The USB port powering or charging device may include a communication circuits. The communication circuit is connected to the AC socket and to the USB port, and is configured to convey bidirectional serial data of the USB port over the AC wires.

A method for modifying an AC fixture to provide a USB powering or charging device is described. A faceplate of an AC fixture is replaced with a faceplate of a USB powering or charging device. The AC socket of the AC fixture is attached to a circuit board of the USB powering or charging device. The AC socket and the circuit board are assembled into a housing. The housing is assembled with the AC socket and the circuit board into a location of the AC fixture. The faceplate of the USB powering or charging device is attached over the AC socket, a circuit board and the housing. The USB powering or charging device has a USB port providing DC power converted by the circuit board from the AC power of the AC socket.

A fault lamp may be included in the USB powering or charging device. Upon connecting AC wires to the AC socket applying the AC power, the fault lamp illuminates in response to an incorrect connection of the AC wires. The fault lamp does not illuminate if the AC wires are connected correctly.

### BRIEF DESCRIPTION OF THE DRAWINGS

FIG. 1 is a perspective view of a USB powering or charging device that is housed within an AC outlet.

FIG. 2 shows an exploded view of the USB powering or charging device of FIG. 1.

FIG. 3 shows a circuit diagram for the USB powering or charging device of FIG. 1, with a switch and a fault detect lamp.

FIGS. 4A and 4B show a further circuit diagram for the USB powering or charging device of FIG. 1, with a fault detect lamp.

### DETAILED DESCRIPTION

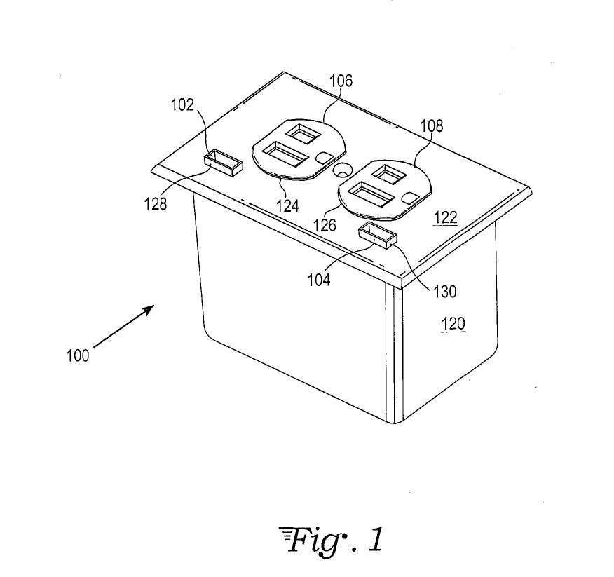

With reference to FIG. 1, the USB powering or charging device 100 has one or more USB ports 102 and 104, each of which has a USB socket conforming with the USB standard. Each USB port is located adjacent to an AC socket 106 and 108. The USB port and the AC socket are part of a modified AC fixture, such as a standard home or commercial AC outlet for mounting on a wall.

In various examples, the USB powering or charging device may have a single USB port and a single AC socket, two USB ports 102 and 104 and two AC sockets 106 and 108 as shown in FIG. 1, two USB ports and a single AC socket, a single USB port and two AC sockets or another combination of USB ports and AC sockets. More than two ports or two sockets may be used.

In another example, the USB powering or charging device may have a lamp or other type of indicator mounted to the faceplate of the AC fixture. The lamp or other indicator may be used to alert an installer or a user of a wiring fault.

A USB port such as a USB power port may be used as a power providing source for devices. A USB power port resembles a standard USB port, in an example where data transfer is not used but the USB port is used for powering applications such as a reading light, an aquarium, a battery charger or other non-USB-data-responsive device. Any unused pins in a USB power port may be left open, shorted or have circuitry to prevent data or safety problems, as can be devised by a person skilled in the art and as appropriate to the usage. Labeling or some other visual indicator may be applied to any of the USB port, a USB port used as a power receptacle or any of the wiring connection terminals so that a USB plug or any wiring is inserted or otherwise connected properly, with any pins correctly oriented relative to a plug or a receptacle. The labeling or other visual indicator may be applied to one or more locations on a faceplate of the device, and may align with markings on USB plugs or cables.

A USB cable can be plugged into any of the USB ports of the USB powering or charging device. The other end of the USB cable can be plugged into a USB device to be powered or charged. In an example, one end of a USB cable can be plugged into the USB powering or charging device, and the other end of the USB cable can be plugged into a USB port of a peripheral device.

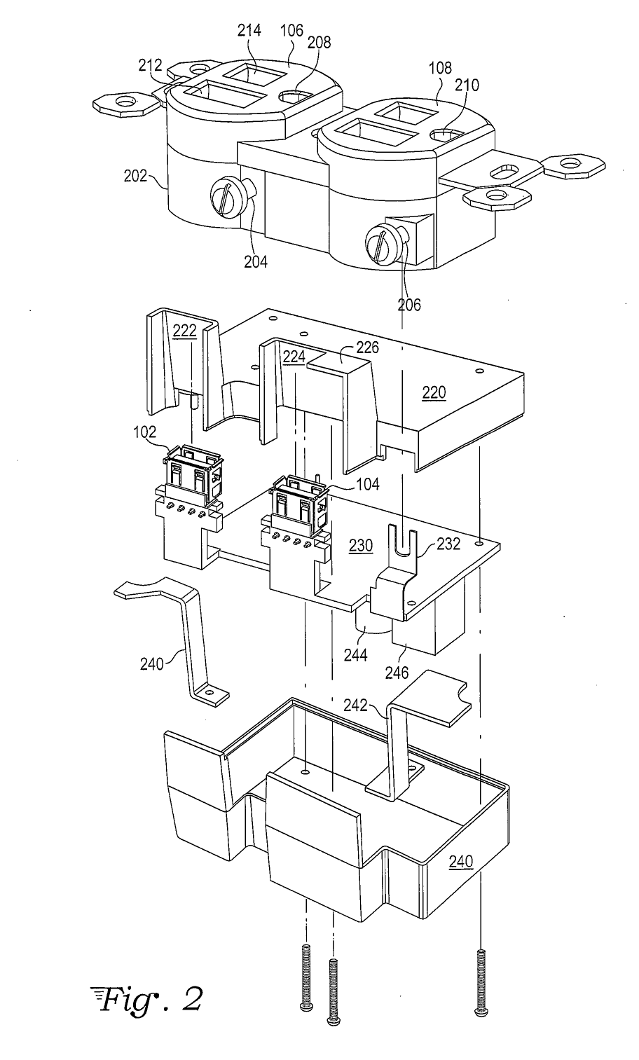

With reference to FIG. 2, physical and electrical components of the USB powering or charging device 100 are shown. An AC socket block 202 may be a double socket or duplex as shown in FIG. 2 or may have a single or other number of sockets. The AC socket block 202 has mounting holes, terminals 204 and 206 for AC wires and one or more three-prong AC sockets 106 and 108 for receiving a standard three prong plug. As is customary, the rounded hole 208 and 210 in the three-prong AC socket is connected to earth ground and receives the rounded prong of the standard three prong plug. The longer 212 of the two rectangular slots in the three-prong AC socket is connected to the neutral wire, which is a type of floating ground, and the shorter 214 of the two rectangular slots in a three-prong AC socket is connected to the line voltage, also known as the “hot” wire or terminal. A top case 220, which may be of molded plastic, has mountings 222 and 224 for one or more USB ports and may have a mounting 226 for a lamp.

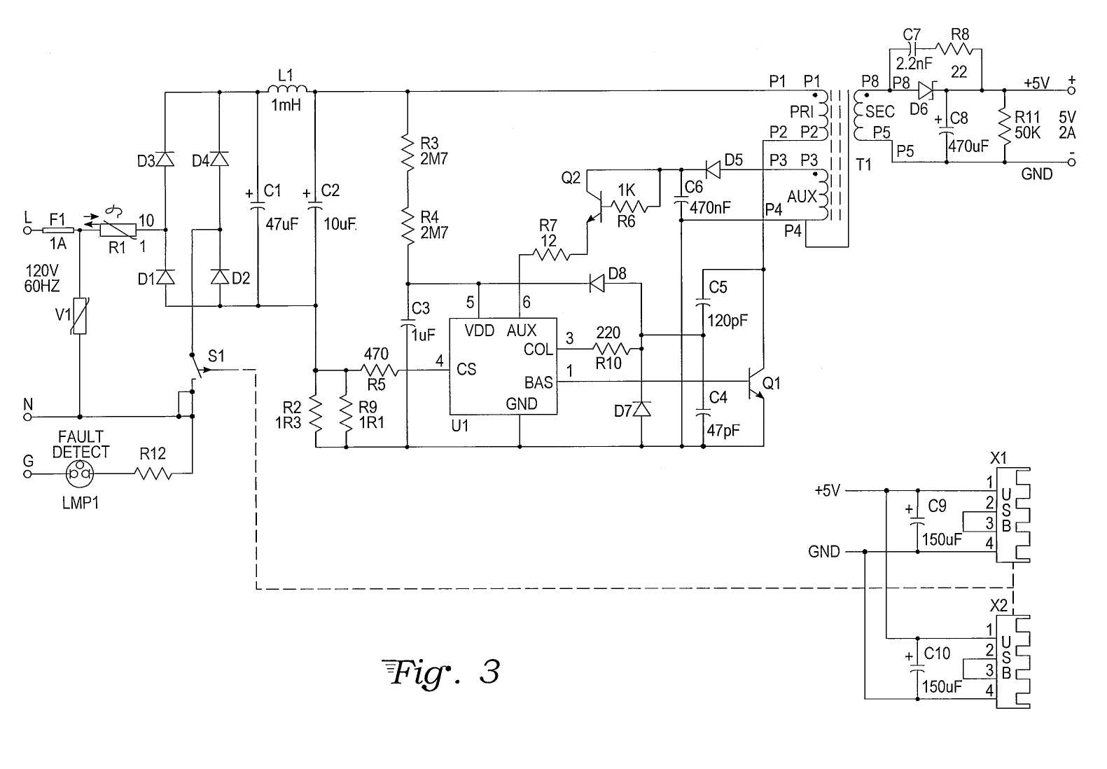

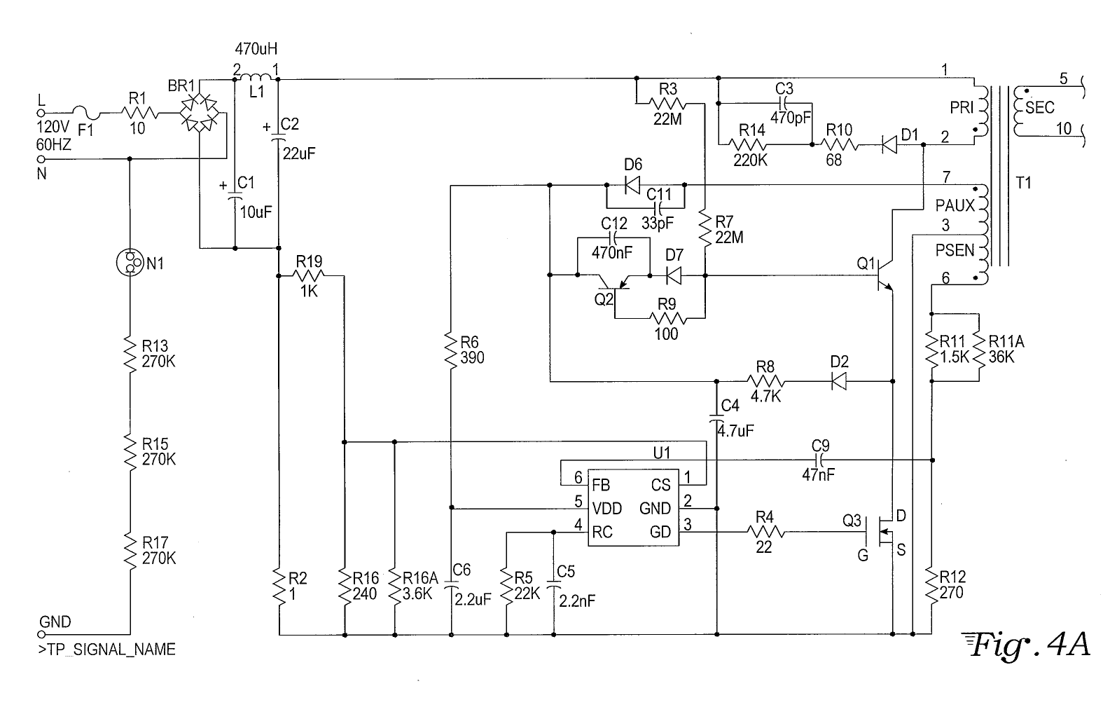

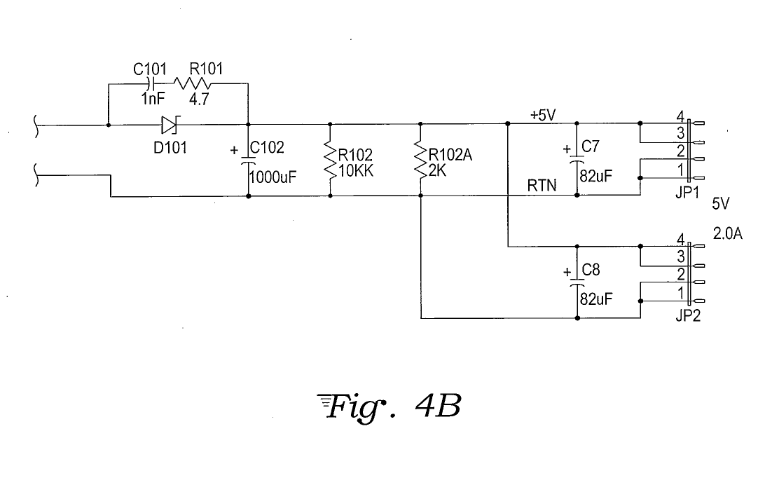

A circuit board 230 has circuit traces and any mountings for electronics components. The circuitry of the circuit board will be discussed with reference to FIGS. 3 and 4. The USB port or ports 102 and 104 may be mounted to the circuit board. Earth ground, neutral and line wires from the household AC wiring are connected to both the AC socket block and the circuit board. A ground strap 232 connects from the circuit board 230 to the neutral connection 206 of the AC socket block 202. As known in the art, a circuit board may include multiple circuit boards, sub boards, circuitry and components.

A bottom case 240, which may be of molded plastic, fits with the top case 220. The circuit board 230 can be mounted to the top case 220, the bottom case 240 or both cases, or may be sandwiched between the top case and bottom case. Top steel “L” bracket 240 and bottom steel “L” bracket 242 mount to the bottom case 240 and support the circuit board 230 and/or the top case 220. The top case, circuit board and bottom case are then placed inside the small box (not shown). The AC socket block is placed atop the top case, and the AC socket block, top case, circuit board, bottom case and small box are placed inside the large box 120. In a variation, the small box is not used, and the AC socket block, top case, circuit board and bottom case are placed inside the large box 120. A faceplate 122 is fitted atop the AC socket block. With reference back to FIG. 1, the faceplate 122 has openings 124 and 126 for one or more AC sockets 106 and 108 and openings 128 and 130 for one or more USB ports 102 and 104. The faceplate may have an opening or mounting for a lamp.

With reference to FIG. 3, the circuit diagram or schematic shows the circuitry for converting 120 V 60 Hz AC, as commonly used in household and business AC wiring, to 5 V 2 A DC, and supplying the DC voltage and current to one or more USB ports. Other voltage conversion, regulation or generation circuits may be devised by a person skilled in the art, and the DC voltage supplied to the USB port may vary within tolerance limits, such as between 4.75 and 5.25 V or have other current limits such as 100 mA from each receptacle or 400 mA total.

In the circuit of FIG. 3, the AC line voltage and current are rectified by a diode bridge of diodes D1, D2, D3 and D4. Fuse F1 provides overcurrent protection. Rectified voltage and current are filtered by capacitors C1 and C2 and inductor L1, then converted or regulated by U1 and various resistors, capacitors, discrete transistors, diodes and a transformer T1, and smoothed by various resistors, capacitors and a Zener diode D6, to produce a regulated DC voltage and current. The regulated DC voltage and current are distributed to one or more USB ports X1 and X2. Various discrete components and the IC U1 may form a switching regulator or other type of DC to DC converter or regulator.

Generally, a power supply circuit suitable for the USB powering or charging device 100 includes a rectifier for rectifying AC voltage to DC voltage as rectified AC voltage, and a regulator for producing a regulated DC voltage from the rectified AC voltage. The regulator section may include smoothing circuitry that reduces the ripple of the rectified AC voltage. The regulator section may regulate the DC voltage from the rectified AC voltage down to a lower DC voltage in a manner known in the art, such as by smoothing and dropping the DC voltage, using a DC to DC voltage conversion or a switching regulator employing a transformer and pulse logic controlled by feedback. A circuit breaker or a fuse may be placed in line with the hot AC voltage line. The power supply circuit may use a switch activated by insertion of a USB plug into a USB socket, the switch enabling or disabling a portion of the circuitry of the power supply circuit. A power supply circuit may make use of a transformer to step down the AC voltage to a lower AC voltage at a higher current, followed by rectification and regulation. A power supply circuit may rectify the AC voltage directly from the AC connection, followed by rectification and regulation. A transformer may be used to transform the AC voltage or to transform a pulsed DC voltage, as in a switching regulator.

In an example, one or more USB ports are mounted on the negative side of a three prong AC socket, closer to the longer or neutral-connected slot of the AC socket then to the shorter or hot-connected slot of the AC socket. Underwriters Lab may require such a mounting, for safety reasons. Underwriters Lab may have applicable standards or restrictions concerning mounting of AC and/or DC devices behind a faceplate of an AC fixture. The lamp mounted to the top case illuminates if the wires to the two current-carrying terminals of the AC socket are reversed during installation in a wiring error. Thus, the lamp and a tester circuit for detecting a wiring reversal form a built-in tester for the USB powering or charging device, informing the installer or a user of an incorrect installation or a wiring fault. The tester circuit may be part of the circuit board.

A further example reduces electrical energy consumption and thus provides energy savings. Power to the USB port only activates when a USB cable is plugged into the USB port. A micro switch or other physical detection means is switched on when the USB cable is plugged into the USB port, and the switch switches on the electrical power circuitry, which then provides DC power to the USB port. The USB powering or charging device thus physically detects a plug insertion to the USB port, and only switches on power under those circumstances. The micro switch or other physical detection means is engaged by a portion of the USB connector or plug at the end of the USB cable being plugged into the USB port. By switching off the electrical power circuitry when a USB cable is not plugged into the USB port, the device saves energy.

The circuit diagram of FIG. 3 has an added switch S1 and an added fault detect lamp LMP1. The switch S1 is located in an electrical connection between the neutral terminal N and the diode bridge, and is physically connected to the USB port. The switch S1 is closed either directly or by a mechanical actuator when the USB plug is connected to the USB port at X1 or X2. By disconnecting the rectifier bridge of diodes D1, D2, D3 and D4 from the neutral terminal N when a USB plug is not connected to the USB port, the device saves power when a USB plug is not connected, and only powers up the rest of the circuitry when a USB plug is connected. Other electrical and physical placements of a switch or types of switch may be devised by a person skilled in the art.

With further reference to FIG. 3, a fault detect lamp LMP1 and current-limiting resistor R12 are connected in line with the ground terminal G. The fault detect lamp LMP1 will light if the neutral wire is hot, such as when a wiring error has reversed the neutral terminal N and the ground terminal G of the device in connecting to neutral and ground of a building wiring. Other placements of a fault detect lamp, types of lamps, or components and circuits supporting a lamp may be devised by a person skilled in the art.

With reference to FIGS. 4A and 4B, a further circuit suitable for the USB powering or charging device is shown. Similarly to the circuit of FIG. 3, the schematic of FIGS. 4A and 4B shows the circuitry for converting 120 V 60 Hz AC, as commonly used in household AC wiring, to 5 V 2 A DC, and supplying the DC voltage and current to one or more USB ports, in this example to two USB ports connected to jumpers JP1 and JP2. Other voltage conversion, regulation or generation circuits may be devised by a person skilled in the art, and the DC voltage supplied to the USB port may vary within tolerance limits, such as between 4.75 and 5.25 V or have other current limits such as 100 mA from each receptacle or 400 mA total.

In the circuit of FIGS. 4A and 4B, the AC line voltage and current are rectified by a diode bridge BR1. Fuse F1 provides overcurrent protection. Rectified voltage and current are filtered by capacitors C1 and C2 and inductor L1, then converted or regulated by U1 and various resistors, capacitors, discrete transistors, diodes and a transformer T1, and smoothed by various resistors, capacitors and a Zener diode D101, to produce a regulated DC voltage and current. The regulated DC voltage and current are distributed to one or more USB ports at JP1 and JP2. Various discrete components and the IC U1 may form a switching regulator or other type of DC to DC converter or regulator.

With further reference to FIG. 4A, a fault detect lamp N1 and current-limiting resistors R13, R15 and R17 are connected in line with the ground terminal G. The fault detect lamp N1 will light if the neutral wire is hot, such as when a wiring error has reversed the neutral terminal N and the ground terminal G of the device in connecting to neutral and ground of a building wiring. Other placements of a fault detect lamp, types of lamps, or components and circuits supporting a lamp may be devised by a person skilled in the art.

A USB port providing DC power to a USB cable and a device connected to such a cable makes use of two pins, for plus and minus terminals of a DC voltage. However, two additional pins are available at a USB port, the additional data pins being for data plus and data minus of a differential bidirectional serial data interface. For a power or charging port that does not transfer data, data plus and data minus may be shorted.

In an example, a USB port of the USB powering or charging device can send and receive signals and data through the AC wires of the household wiring. An electronic circuit which can communicate signals and data to and from the USB port and to and from the AC wires provides AC and DC isolation, signal and data separation and conditioning. Another USB port, which may be on a differing USB powering or charging device at a separate AC socket connected to the same building AC wiring, connects to a computing device such as a personal computer, and may or may not provide DC power or charging back through the USB port of the computing device. In this manner, the computing device may communicate over household or commercial building AC wires with a USB device to be powered or charged. The USB device to be powered or charged has a first USB cable plugged into a first USB powering or charging device at a first AC socket, and the computing device has a second USB cable plugged into a second USB powering or charging device at a second AC socket, with household or commercial building AC wiring between the first and second AC sockets.

In order to communicate data over AC wiring between a first AC socket and a second AC socket, various means may be devised. A data stream may be capacitively coupled to the AC wires at the first AC socket and modulated over the AC wires, then a capacitively decoupled from the AC wires at the second AC socket using suitable coupling and modulation/demodulation circuitry. The modulation and demodulation may be at the applicable data rates, or may involve up conversion to a higher frequency and down conversion from the higher frequency to the data rate. Suitable filtering to remove the AC line frequency e.g. 60 Hz at the receiving end may be applied, along with data recovery circuitry. Data or a data stream may be embedded in or include a clock signal, and the clock signal may be recovered at the receiving end by suitable clock recovery circuitry. Data may be sent directly in a modulated format resembling or related to the USB standard albeit at appropriate voltage levels for AC line modulation, or the data may be accompanied by additional network-related packet information or other data so that the AC lines are used as a network. Collision protocols or circuitry may be included for more reliable communication. Communication may be point to point or have a limited number of specified addresses, or may be generally networked, with appropriate protocols and circuitry included in the port powering or charging device. Communication may be unidirectional or bidirectional, and may be simplex, half duplex or full-duplex, make use of time division multiplexing or other multiplexing schemes or known aspects of communication technology.

In a further example, a method is described for modifying an existing AC socket, and installing components of the USB powering or charging device. AC power is disconnected from the existing AC socket, by turning off a circuit breaker or removing a fuse. The existing faceplate is removed and replaced by the faceplate of the USB powering or charging device. The AC wires are connected to the circuit board of the USB powering or charging device. The AC socket, top case with lamp, circuit board, bottom case, small box if used and large box are assembled, and installed at the location where the existing AC socket was previously installed. The faceplate of the USB powering or charging device is attached on top of the newly modified AC socket, all wiring is checked and components secured. Power is restored to the AC socket by turning on the circuit breaker or replacing the fuse. The resultant modified AC socket, with components of the USB powering or charging device, provides DC power to one or more USB ports and may provide signal and data connections over the AC wiring to the one or more USB ports. In variations, the method includes adding communication circuitry so that the resultant modified AC socket, with components of the USB powering or charging device, provides data communication over the AC lines.

In a still further example, the USB powering or charging device saves power as compared with the use of a personal computer. When a user desires to power a USB device that does not need immediate data connection through the USB port, such as a lamp, a battery charger or an MP3 player playing songs from previously filled onboard memory, plugging the USB device into the USB powering or charging device provides power. Plugging the selfsame USB device into a USB port of a personal computer, to provide power to the USB device when the computing capability of the personal computer is not needed, wastes electrical power as compared with the use of the USB powering or charging device.

Other connectors, standards, signals, data and ports may be applied to the device and method as described above. FireWire, mini-USB, HDMI and other connections and standards may be used to communicate among peripherals and computing devices and over AC wiring, with or without DC power provided to a port for such a connection. A port powering or charging device, an AC line port communication device, an AC line port powering or charging and communication device or other variations may be devised based upon the USB powering or charging device.

The USB powering or charging device may save energy, provide power or charging to a USB port for connection to a USB device, and provide a data connection for a USB port, at an AC fixture.

What is claimed is:

1. A port powering or charging device comprising:
a circuit board connectable to an AC socket and having a power circuit and a port; and
a housing containing the circuit board and to which the AC socket is mountable, the housing being mountable to or within a wall of a dwelling;
wherein the power circuit is configured to convert AC power from the AC socket to DC power and deliver the DC power to the port.

2. The port powering or charging device of claim 1 wherein the port is a USB port.

3. The port powering or charging device of claim 1 wherein the port is one of a FireWire, a mini-USB or an HDMI port.

4. The port powering or charging device of claim 1 further comprising a fault circuit having an indicator and configured to activate the indicator in response to a wiring fault at the AC socket.

5. The port powering or charging device of claim 4 wherein the indicator is a lamp.

6. The port powering or charging device of claim 1 further comprising a data circuit configured to communicate data to and from the port over AC wires.

7. The port powering or charging device of claim 1 wherein a switch turns off a portion of the power circuit in the absence of a device inserted into the USB port.

8. The port powering or charging device of claim 1 wherein the power circuit includes a switching regulator or a DC to DC converter.

9. A USB port powering or charging device comprising:
an AC socket connectable to AC wires;
a circuit board connected to the AC socket and having a power circuit and a USB port; and
a housing containing the circuit board and to which the AC socket is mounted, the housing being mountable to or within a wall of a dwelling;
wherein the power circuit is configured to convert AC power from the AC socket to DC power and deliver the DC power to the USB port.

10. The USB port powering or charging device of claim 9 further comprising:
a lamp mounted to the circuit board; and
a tester circuit attached to the lamp and to the AC socket;
wherein the tester circuit is configured to activate the lamp upon a wiring reversal at the AC socket.

11. The USB port powering or charging device of claim 9 further comprising a communication circuit connected to the AC socket and to the USB port and configured to convey bidirectional serial data of the USB port over the AC wires.

12. The USB port powering or charging device of claim 9 further comprising a switch disconnecting AC power to at least a portion of the power circuit in response to an absence of a device inserted into the USB port.

13. The USB port powering or charging device of claim 9 wherein the power circuit includes a bridge rectifier and a DC to DC converter.

14. The USB port powering or charging device of claim 9 wherein the USB port is mounted closer to a neutral slot of the AC socket than to a hot slot of the AC socket.

15. A method for modifying an AC fixture to provide a USB powering or charging device, the method comprising:
replacing a faceplate of an AC fixture with a faceplate of a USB powering or charging device;
attaching an AC socket of the AC fixture to a circuit board of the USB powering or charging device;
assembling the AC socket and the circuit board into a housing;
assembling the housing with the AC socket and the circuit board into a location of the AC fixture; and
attaching the faceplate of the USB powering or charging device over the AC socket, the circuit board and the housing;
wherein the USB powering or charging device has a USB port providing DC power converted by the circuit board from AC power of the AC socket.

16. The method of claim 15 further comprising:
connecting AC wires to the AC socket and applying the AC power, wherein a fault lamp of the USB powering or charging device illuminates in response to an incorrect connection of the AC wires and does not illuminate in response to a correct connection of the AC wires.

17. The method of claim 15 wherein a switch connects power from the AC socket to a portion of the circuit board of the USB powering or charging device in response to a presence of a device inserted into the USB port.

18. The method of claim 15 wherein the circuit board further includes a communication circuit configured to convey data of the USB port over the AC wires.

19. The method of claim 15 wherein the circuit board includes a bridge rectifier and a DC to DC converter.

20. The method of claim 15 further comprising mounting the USB port closer to a neutral slot of the AC socket than to a hot slot of the AC socket.
